(19) United States
(12) Patent Application Publication
(10) Pub. No.: US 2009/0309521 A1
(43) Pub. Date: Dec. 17, 2009

(54) Driver for MEMS device

(75) Inventors: Harold Gee Yee, Chandler, AZ (US); Robert Allen Kimball, Gilbert, AZ (US)

Correspondence Address: Paul F. Wille;Cantor Colburn LLP, 22nd Floor, 20 Church St., Hartford, CT, 06103-3207, US

(73) Assignee: World Properties, Inc., Lincolnwood, IL (US)

(21) Appl. No.: 12/214,164

(22) Filed: Jun. 17, 2008

(51) Int. Cl. B81B 7/02

(52) U.S. Cl. 318/116

(57) ABSTRACT

A driver for electrically causing a MEMS device to change shape or position includes an amplifier having a first feedback loop and a second feedback loop. The first feedback loop stabilizes output voltage and the second feedback loop reduces current changes through the MEMS device to zero.

### FIELD OF THE INVENTION

This invention relates to microelectromechanical systems (MEMS) and, in particular, to a driver for operating such systems.

### BACKGROUND OF THE INVENTION

MEMS technology adapts processing techniques from making integrated circuits on silicon wafers to produce mechanical structures 10-100 μm (0.001-0.1 mm) in size. Such structures have found application in ink jet printers, accelerometers, gyroscopes, pressure sensors, autofocus systems in cameras for cellphones, and other optical technologies.

For many applications, cantilever arms are formed on a silicon wafer. The arms serve as a support for a lens, mirror, or other device. Within a limited range of displacement, the arms are a resilient support and provide a restoring force to oppose a displacing force supplied by electrostatic means or by electromagnetic means. The publication Proc. SPIE vol. 6502 paper 36 “MEMS Digital Camera” by Gutierrez et al. describes a lens on a MEMS motion control stage and displaced by an electromagnetic actuator, sometimes called a “voice coil” actuator. The driver disclosed for the voice coil actuator is an integrated circuit, type AD5398 from Analog Devices, Inc. See U.S. Pat. No. 6,661,962 (Calvet et al.) and Published Patent Application No. 2005/0249487 (Gutierrez) for electrostatic displacement devices.

In any mechanical system, motion is the result of a sum of several competing forces. A persistent problem in positioning systems is momentum. Once started, the device must be brought to rest at the desired location. For auto-focusing systems, the change must be effected in a minimum amount of time. Another problem in mechanical systems is resonance. Driving a system at resonance can cause self-destruction, as shown by the famous Tacoma Narrows Bridge on Nov. 7, 1940. Driving a system off resonance can cause ringing or oscillation, which will eventually stop. U.S. Pat. No. 4,882,933 (Petersen et al.) proposes using viscous (air) damping for a MEMS accelerometer. Tiny baffles control air flow and prevent excessive motion. Such a system achieves critical damping only by chance.

It is known in the art to use very sophisticated techniques to calculate or predict motion; e.g. see U.S. Pat. No. 7,085,096 (Baek et al.), which discloses such a control system for positioning the read/write head in a disk drive. Although effective, such techniques are relatively expensive and require relatively large circuits. What is needed in the art is a driver for electrostatic MEMS that can be contained in a single integrated circuit and are relatively low in cost.

By definition, MEMS devices are small. A driver that is significantly larger than the MEMS device itself is undesirable. Implementing a driver as an integrated circuit can minimize size but the size of an integrated circuit means little if the circuit needs external components. Thus, it is desired to have a small driver, e.g. less than four square millimeters, with no external components.

In view of the foregoing, it is therefore an object of the invention to provide an improved driver for electrostatic MEMS.

Another object of the invention is to provide a relatively simple driver that can be implemented as a low cost, integrated circuit.

A further object of the invention is to provide a driver for electrostatic MEMS that minimizes ringing.

Another object of the invention is to provide a driver for electrostatic MEMS that provide precise displacement.

A further object of the invention is to provide a small driver that requires no external components.

### SUMMARY OF THE INVENTION

The foregoing objects are achieved by this invention in which a driver for electrically causing a MEMS device to change shape or position includes an amplifier having a first feedback loop and a second feedback loop. The first feedback loop stabilizes output voltage and the second feedback loop reduces current changes through a MEMS device to zero.

### BRIEF DESCRIPTION OF THE DRAWINGS

A more complete understanding of the invention can be obtained by considering the following detailed description in conjunction with the accompanying drawings, in which:

FIG. 1 is a block diagram of the AD5398 driver;

FIG. 2 is a block diagram of a driver constructed in accordance with a preferred embodiment of the invention;

FIG. 3 is a block diagram of a driver constructed in accordance with an alternative embodiment of the invention;

FIG. 4 is a chart of displacement versus voltage for a MEMS device; and

FIG. 5 is a chart of capacitance versus displacement for a MEMS device.

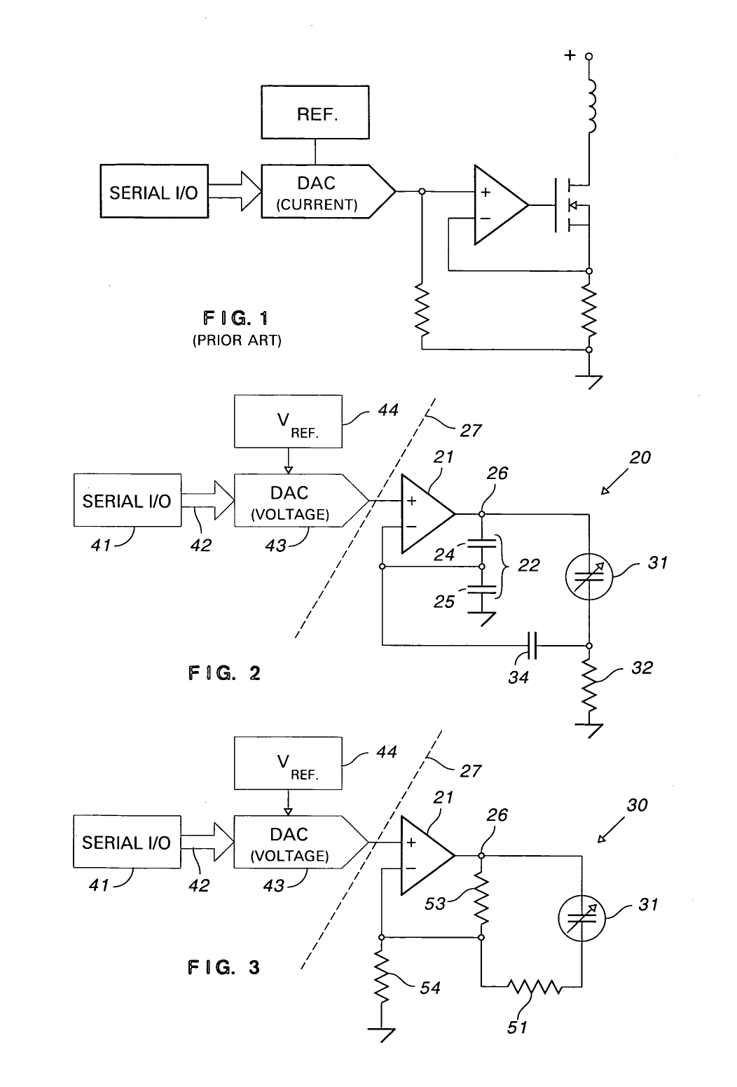

### DETAILED DESCRIPTION OF THE INVENTION

FIG. 2 illustrates a preferred embodiment of the invention in which driver 20 includes operational amplifier 21 having a pair of inputs and an output coupled to node 26. Voltage divider 22 is coupled between node 26 and ground. In a preferred embodiment of the invention, voltage divider 22 includes capacitor 24 coupled in series with capacitor 25, with the junction of the capacitors coupled to the inverting (−) input of amplifier 21.

Amplifier 21 has a gain greater than one and converts the voltage on the non-inverting (+) input to a higher voltage at node 26. The ratio of the capacitances of capacitors 24 and 25 is preferably approximately the same as the gain of amplifier 21. In other words, if amplifier 21 has a gain of thirty, then the ratio of the capacitance of capacitor 24 to the capacitance of capacitor 25 is approximately 30:1. This is a first feedback loop.

A MEMS device, represented by variable capacitor 31, is coupled to node 26 and is coupled to ground by resistor 32. A MEMS device is actually a complex impedance having both resistive and reactive components.

Resistor 32 serves two functions, in addition to completing a circuit through MEMS device 31. Resistor 32 damps current changes through MEMS device 31, reducing mechanical ringing. The time constant, not the settling time, of MEMS device 31 and resistor 32 is preferably approximately 3 ms. Settling time is approximately 10 ms. Resistor 32 is also a current to voltage converter. The voltage drop across resistor 32 is coupled to amplifier 21 by capacitor 34, which blocks direct current. In this way, only alternating current, i.e. changes in current, are coupled to amplifier 21. This is a second feedback loop.

MEMS device 31 is positioned in accordance with a control voltage from a suitable source. One such source is illustrated to the left of dashed line 27. Serial interface 41 converts serial data into parallel data. In one embodiment of the invention, ten bits of data were coupled over bus 42 to digital to analog converter (DAC) 43. The output from converter 43 is coupled to one input of operational amplifier 21.

Ten bit resolution for converter 43 has been found to provide a reasonable compromise between precision and speed. Data may be organized into groups or bytes that are bundles of four or eight bits. If there are more than ten bits sent to interface 41, considerations outside the scope of this invention would dictate whether the lower, higher or middle ten bits are sent to converter 43.

Converter 43 divides a reference voltage from source 44 into a smaller voltage determined by the data from interface 41. Ten bits correspond to the range 0-1043. Thus, a one volt reference can be divided into steps slightly smaller than one millivolt. In one embodiment of the invention, the reference voltage was 1.2 volts and the steps were slightly greater than one millivolt each.

Amplifier 21, capacitor 24, and capacitor 25 form a stabilized voltage source. During operation, the stabilized voltage is de-stabilized by a change in output voltage from converter 43 or by a change in voltage from capacitor 34. Current through MEMS device 31 is converted to a voltage and changes in voltage are coupled by capacitor 34 to the inverting input of amplifier 21. Thus, the second feedback loop reduces current changes to zero.

In FIG. 3, driver 30 is similar to driver 20, illustrated in FIG. 2, and operates in substantially the same way. The voltage on node 26 is divided by the voltage divider including resistors 53 and 54. The ratio of the resistances is preferably approximately the same as the gain of amplifier 21. The current through MEMS device 31 is coupled to the junction of resistors 53 and 54 by coupling resistor 51. MEMS devices are very low current devices, on the order of tens of microamps. Thus, the current path through MEMS device 31 can be returned through the voltage divider. During operation, the voltage on node 26 is stabilized by the feedback loop through resistors 53 and 54. The voltage on node 26 is changed by a change in output voltage from converter 43 or by a change in current through MEMS device 31, such as might be caused by ringing or overshoot.

FIG. 4 is a chart of displacement versus voltage for a MEMS device. The actual numbers depend upon the construction of the device but a voltage of 0-30 volts can be considered typical for an electrostatically driven device. Similarly a displacement of 0-100 μm can be considered typical for an electrostatically driven device. The curve in FIG. 4 is substantially linear. A linear relationship is indicated by the dashed line.

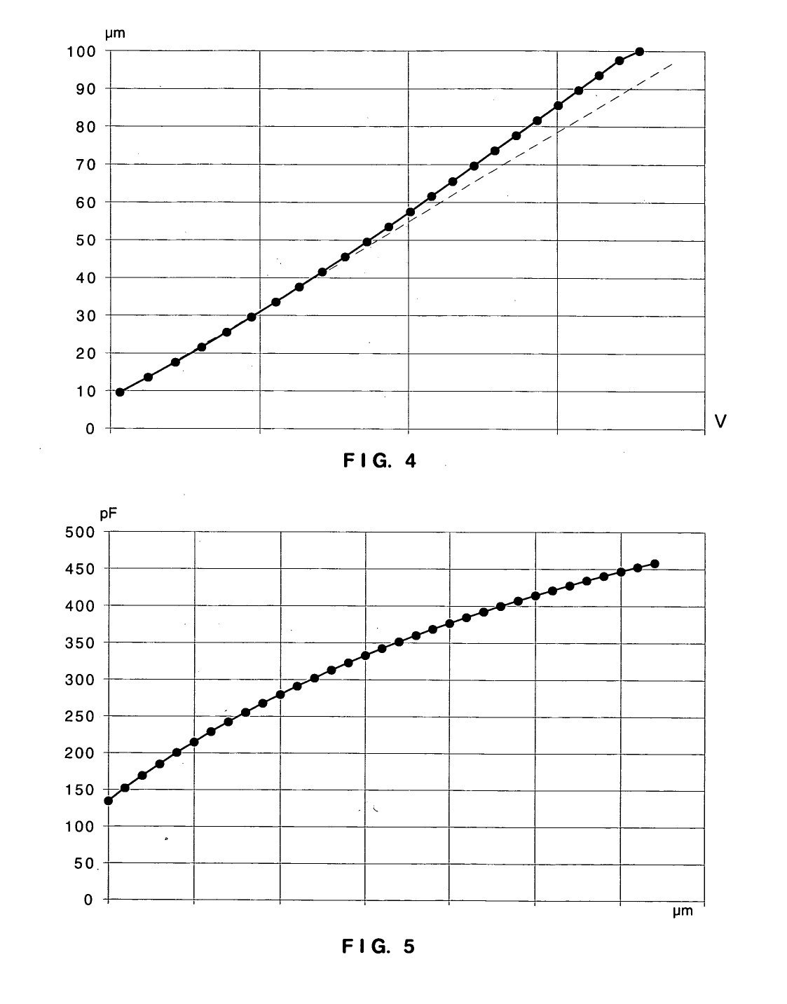

FIG. 5 is a chart of capacitance versus displacement for a MEMS device. The variation is non-linear, which makes calibration somewhat more difficult. What FIG. 4 and FIG. 5 do not illustrate is the variation in voltage as a device is actuated. Depending upon physical load, the amount of displacement desired, and other factors, a change in the capacitance of MEMS device 31 causes a change in the voltage across the device, in addition to whatever voltage change may have been caused by a change in data to converter 43. The voltages can be additive or opposing. If additive, the device may overshoot the desired displacement. If opposing, the device may undershoot the desired displacement. These small changes, combined with momentum and other effects, can lead to errors.

In accordance with the invention, combining the two feed back loops minimizes problems with undershoot, overshoot, and ringing. A voltage feedback loop monitors the magnitude of the output voltage and stabilizes the voltage on MEMS device 31. A current feedback loop through the MEMS device reduces any ringing that may occur.

The invention thus provides an improved driver for electrostatic MEMS that can be implemented as a low cost, integrated circuit. The driver minimizes ringing and provides precision movement. When implemented as an integrated circuit, the embodiment of FIG. 2 needs no external components, or, at most, one external component. Thus, an integrated circuit having an area of four square millimeters is obtained.

Having thus described the invention, it will be apparent to those of skill in the art that various modifications can be made within the scope of the invention. For example, although illustrated as a single amplifier, amplifier 21 can be implemented with plural stages of amplification. The feedback loops can be associated with separate amplifiers rather than a single amplifier. The voltage divider could be referenced high (coupled to the supply voltage) rather than to ground. Elements shown as single can be implemented as plural elements, e.g. parallel capacitors, as may be expedient in making an integrated circuit. Although an object of the invention is to provide a circuit that is readily implemented as a single integrated circuit, the circuit can be implemented as a plurality of devices. The source of a control voltage is not critical and can be analog or digital. Filtration can be used to smooth variations in the control voltage if desired.

What is claimed is:

1. A driver for electrically causing a MEMS device to change shape or position, said driver comprising:
an amplifier having a first feedback loop and a second feedback loop;
wherein said first feedback loop stabilizes output voltage and said second feedback loop stabilizes current through a MEMS device.

2. The driver as set forth in claim 1 wherein said amplifier exhibits gain, a, and said first feedback loop includes a voltage divider that divides an applied voltage by approximately α.

3. The driver as set forth in claim 2 wherein the applied voltage is the output voltage, V, of said amplifier and the voltage V/α is coupled back to an input of said amplifier.

4. The driver as set forth in claim 1 and further including:
a digital to analog converter coupled to an input of said amplifier, wherein data applied to said digital to analog converter causes a change in the output voltage of said amplifier and a change in position of a MEMS device coupled to said driver.

5. The driver as set forth in claim 4 wherein said digital to analog converter is a ten-bit converter.

6. The driver as set forth in claim 4 and further including:
a serial interface coupled to said converter.

7. A driver for electrically causing a MEMS device to change shape or position, said driver comprising:
an amplifier having a first input and a first output;
a digital to analog converter having an output coupled to said first input, thereby controlling the nominal output voltage of said amplifier;
a first impedance and a second impedance connected in series and having a junction coupled to a second input of said amplifier;
a third impedance coupling said MEMS device to said junction.

8. The driver as set forth in claim 7 wherein said third impedance includes a capacitor.

9. The driver as set forth in claim 7 wherein said third impedance includes a resistor.

10. The driver as set forth in claim 7 wherein said first impedance includes a capacitor and said second impedance includes a capacitor.

11. The driver as set forth in claim 7 wherein said digital to analog converter is a ten-bit digital to analog converter.

12. The driver as set forth in claim 7 and further including:
a serial interface coupled to said digital to analog converter.
